(19) United States
(12) Patent Application Publication
(10) Pub. No.: US 2008/0185661 A1
(43) Pub. Date: Aug. 7, 2008

(54) Semiconductor device and method for fabricating the same

(76) Inventor: Shinji Takeoka, Toyama (JP)

Correspondence Address: MCDERMOTT WILL & EMERY LLP, 600 13TH STREET, NW, WASHINGTON, DC, 20005-3096, US

(21) Appl. No.: 11/976,666

(22) Filed: Oct. 26, 2007

(30) Foreign Application Priority Data
Feb. 1, 2007 (JP) 2007-022899

(51) Int. Cl. H01L 27/088; H01L 21/8234

(52) U.S. Cl. 257/384; 438/275; 257/E27.06; 257/E21.616

(57) ABSTRACT

A first MIS transistor includes: a first gate insulating film formed on a first active region; a first gate electrode formed on the first gate insulating film; first sidewall insulating films formed on side surfaces of the first gate electrode; first source/drain regions formed at outer sides of the first sidewall insulating film in the first active region; a silicide region formed as an upper layer of each of the first source/drain regions; a first underlying insulating film formed over the first active region using ALD so as to cover the first gate electrode, the first insulating films and the silicide region; and a first contact liner film formed on the first underlying insulating film using plasma CVD and made of a stress insulating film for applying a tensile or compressive stress in a gate length direction in a channel region.

### BACKGROUND OF THE INVENTION

The present invention relates to a semiconductor device and a method for fabricating the semiconductor device, and more particularly relates to a field-effect transistor including a contact liner film having a uniform thickness on a wafer surface and a method for fabricating the transistor.

With reduction in the design rule of semiconductor devices, the degree of integration of circuits has been remarkably increased. It is currently possible to mount more than a hundred million field-effect (MIS: metal insulating semiconductor) transistors on a single chip. To achieve such a chip, not only the development of superfine processing technology, such as lithography, etching or the like, which requires processing accuracy of several tens nanometer order is necessary but also high driving power of transistors is strongly required to ensure an absolute amount of a current even when a fine transistor is formed.

In recent years, as a method for improving driving power of a transistor, application of a stress to channel regions has been drawn attentions. In this method, with application of a stress to silicon as a substrate, a band structure of silicon is changed to improve carrier mobility. Known studies have already shown that to improve mobility of an n-channel MIS transistor (NMIS), it is effective to apply a tensile stress to a channel region in a gate length direction. On the other hand, for a p-channel MIS transistor (PMIS), it is effective to apply a compressive stress to a channel region in a gate length direction.

As a method for applying a stress to a channel region, a method using a contact liner film has been proposed (see, for example, Japanese Laid-Open Publication No. 2003-60076).

FIG. 5 is a cross-sectional view illustrating a cross-sectional structure of a known NMIS transistor including a contact liner film for applying a stress in a gate length direction (channel direction).

As shown in FIG. 5, a gate electrode 503 is formed on a semiconductor substrate 501 with a gate insulating film 502 interposed therebetween so as to include a silicide region 507 as an upper layer. In parts of the semiconductor substrate 501 located at both sides of the gate electrode 503, respectively, n-type source/drain regions 504 are formed so as to have a shallow junction depth. On side surfaces of the silicide region 507, the gate electrode 503 and the gate insulating film 502, sidewalls 505 are formed. In parts of the semiconductor substrate 501 located at outer sides of the sidewalls 505, n-type source/drain regions 506 are formed so that each of the n-type source/drain regions 506 includes the silicide region 507 as an upper layer and have a great junction depth. A contact liner film 508 of a silicon nitride film having a tensile stress in a gate length direction is formed over an entire surface of the semiconductor substrate 501 so as to cover the gate electrode 503 and the sidewalls 505. On the contact liner film 508, an interlevel insulating film 509 is formed. In the interlevel insulating film 509, a contact plug 510 is formed so as to pass through the interlevel insulating film 509 and have a lower end reaching an upper surface of part of the silicide regions 507.

Japanese Laid-Open Publication No. 2003-60076 discloses that the known semiconductor device having the above-described structure includes the contact liner film 508 of a silicon nitride film having a tensile stress and thus driving power of an NMIS transistor is improved by 7%.

According to Mistry et al., Symp. on VLSI Tech., Digest of Tech. Papers pp. 50-51 (2004), it is known that driving power of an NMIS transistor is dependent on a thickness of a contact liner film. Also, as clearly understood from the relationship between a contact liner film thickness disclosed in Japanese Laid-Open Publication No. 2003-60076 and change in on-current, driving power of an NMIS transistor is improved by 12% by increasing a thickness of a contact liner film of a nitride film to 80 nm.

From the description above, it can be understood that to improve driving power of an NMIS transistor, it is advantageous to form a contact liner film using a silicon nitride film having a tensile stress and make its thickness as large as possible. Moreover, to improve driving power of a PMIS transistor, a contact liner film having a large compressive stress is preferably used.

A contact liner film of a silicon nitride film having a large tensile or compressive stress is normally formed using plasma CVD.

However, it has been shown that if a silicon nitride film constituting a contact liner film is formed on a semiconductor substrate using plasma CVD so as to cover a gate electrode and sidewalls, a thickness of the silicon nitride film varies on a wafer surface.

Specifically, according to experiments conducted by the present inventor, when a silicon nitride film was formed to have a thickness of 25 nm using plasma CVD, a thickness of part of the silicon nitride film located on a silicide region as an upper layer of each of source/drain diffusion regions was only 20 nm.

As has been described, a silicon nitride film formed using plasma CVD has the dependence on an underlying layer and a thickness of the silicon nitride film is reduced on a silicide region in a doped region, thus resulting in reduction in a tensile or compressive stress of the silicon nitride film as a whole. Accordingly, a problem arises in which improvement of driving power of a MIS transistor by increasing a thickness of a silicon nitride film as a contact liner film is suppressed.

### SUMMARY OF THE INVENTION

In view of the above-described problems, it is an object of the present invention to provide a semiconductor device having a structure which allows elimination of the, dependence of a contact liner film on an underlying film and a method for fabricating the semiconductor device.

To achieve the above-described object, the present inventor has conducted keen examinations to reach the finding that by adopting a structure in which an underlying insulating film formed using ALD (atomic layer deposition) is provided under a contact liner film formed of a stress insulating film having a tensile or compressive stress using plasma CVD (chemical vapor deposition), the dependence of the contact liner film on the underlying film can be eliminated and reduction in thickness of the contact liner film on a silicide region can be prevented. Furthermore, as a material for constituting the underlying insulating film, even some other insulating film such as a silicon oxide film can eliminate the dependence of the contact liner on the underlying film. However, in consideration of integration, an underlying insulating film made of a silicon nitride film is preferably used.

Specifically, in view of integration, important points are that an underlying film itself for eliminating the dependence on an underlying layer does not have the dependence on an underlying layer, that an underlying layer has to be able to be formed so as to have a small thickness for the purpose of increasing a thickness of a contact liner film, and that an underlying layer has to be able to be formed at a low temperature so as to avoid change of properties of a silicide region. A silicon nitride film formed using ALD satisfies all of these important points. When a silicon nitride film is formed using ALD, the film is formed by depositing a layer by a layer, so that the film can be formed so as not to have the underlying layer dependence and so as to have a very small, uniform thickness. Also, the film can be formed at a low temperature of 400° C. or less. Accordingly, properties of a silicide region are not changed. Moreover, in terms of integration, not to complicate contact etching, an underlying film and a contact liner film are preferably made of the same material. For the above-described reasons, each of an underlying insulating film formed using ALD and a contact liner film formed using plasma CVD is preferably made of a silicon nitride film.

In the above-described view, the present invention has been devised. Specifically, a semiconductor device according to one embodiment of the present invention includes: a first MIS transistor formed on a first active region in a semiconductor substrate. In the semiconductor device, the first MIS transistor includes: a first gate insulating film formed lo on the first active region; a first gate electrode formed on the first gate insulating film; first sidewall insulating films formed on side surfaces of the first gate electrode; first source/drain regions formed at outer sides of the first sidewall insulating film in the first active region; a silicide region formed as an upper layer of each of the first source/drain regions; a first underlying insulating film formed over the first active region using ALD so as to cover the first gate electrode, the first insulating films and the silicide region; and a first contact liner film formed on the first underlying insulating film using plasma CVD and made of a stress insulating film for applying a tensile or compressive stress in a gate length direction in a channel region.

In one embodiment of the present invention, it is preferable that in the semiconductor device, the first underlying insulating film is made of silicon nitride film and the first contact liner film is made of a silicon nitride film.

In one embodiment of the present invention, it is preferable that in the semiconductor device, in the silicon nitride film constituting the first underlying insulating film, a composition ratio of nitrogen to silicon is 1.2 or more.

In one embodiment of the present invention, it is preferable that in the semiconductor device, the silicon nitride film constituting the first underlying insulating film has a thickness of 0.3 nm or more and 10 nm or less.

In one embodiment of the present invention, it is preferable that in the semiconductor device, the silicon nitride film constituting the first contact liner film has a thickness of 15 nm or more and 50 nm or less.

In one embodiment of the present invention, it is preferable that in the semiconductor device, the first MIS transistor is an N-type MIS transistor, and the first contact liner film is made of a stress insulating film for applying a tensile stress in the gate length direction in the channel region.

In one embodiment of the present invention, it is preferable that in the semiconductor device, the first MIS transistor is a P-type MIS transistor, and the first contact liner film is made of a stress insulating film for applying a compressive stress in the gate length direction in the channel region.

In one embodiment of the present invention, it is preferable that the semiconductor device further includes a second MIS transistor formed in a second active region which is different from the first active region in the semiconductor substrate, and in the semiconductor device, the second MIS transistor includes: a second gate insulating film formed on the second active region; a second gate electrode formed on the second gate insulating film; second sidewall insulating films formed on side surfaces of the second gate electrode; second source/drain regions formed at outer sides of the second sidewall insulating films in the second active region; a second underlying insulating film formed over the second active region using ALD so as to cover the second gate electrode and the second insulating films; and a second contact liner film formed on the second underlying insulating film using plasma CVD and made of a stress insulating film for applying a tensile or compressive stress in the gate length direction in the channel region, and a thickness of the first contact liner on the silicide region in the first active region is equal to a thickness of the second contact liner film in the second active region.

In one embodiment of the present invention, it is preferable that the semiconductor device further includes an interlevel insulating film formed over the first contact liner film and the second contact liner film; a first contact plug formed so as to pass through the interlevel insulating film and the first contact liner film and reach the silicide region; and a second contact plug formed so as to pass through the interlevel insulating film and the second contact liner film and reach part of the second source/drain regions.

A method for fabricating a semiconductor device according to one embodiment of the present invention includes: the steps of a) forming a first gate insulating film over a first active region in a semiconductor substrate; b) forming a first gate electrode on the first gate insulating film; c) forming first sidewall films on side surfaces of the first gate electrode; d) forming first source/drain regions at outer sides of the first sidewall films in the first active region; e) forming a silicide region as an upper layer of each of the first source/drain regions; f) forming a first underlying insulating film over the first active region using ALD so as to cover the first gate electrode, the first insulating films and the silicide region; and g) forming a first contact liner film on the first underlying insulating film using plasma CVD and made of a stress insulating film for applying a tensile or compressive stress in a gate length direction in a channel region.

In one embodiment of the present invention, it is preferable that in the method, the step f) includes a step of forming the first underlying insulating film of a silicon nitride film; and the step g) includes a step of forming the first contact liner film of a silicon nitride film.

In one embodiment of the present invention, it is preferable that in the method, the step a) includes a step of forming a second gate insulating film on the second active region which is different from the first active region, the step b) includes a step of forming a second gate electrode on the second gate insulating film, the step c) includes a step of forming second sidewall insulating films on side surfaces of the second gate electrode, the step d) includes a step of forming second source/drain regions at outer sides of the second sidewall insulating films in the second active region, in the step e), the silicide region is formed so as not to be located in upper layers of the second source/drain regions, the step f) includes a step of forming a second underlying insulating film on the second active region using ALD so as to cover the second gate electrode and the second sidewall insulating films, and the step g) includes a step of forming a second contact liner film on the second underlying insulating film using plasma CVD and made of a stress insulating film for applying a tensile or compressive stress in the gate length direction in the channel region.

In one embodiment of the present invention, it is preferable that the method further includes after the step g): the step h) of forming an interlevel insulating film on the first contact liner film and the second contact liner film; and the step i) of forming a first contact plug and a second contact plug so that the first contact plug passes through the interlevel insulating film and the first contact liner film and reaches part of the silicide region and the second contact plug passes through the interlevel insulating film and the second contact liner film and reaches part of the second source/drain regions.

As has been described, according to the semiconductor device and the method for fabricating the semiconductor device, the dependence of a contact liner on an underlying film in a silicide region can be eliminated and thus reduction in thickness of the contact liner film can be suppressed. Accordingly, due to increase in thickness of the contact liner film, driving power of an MIS transistor can be improved.

### BRIEF DESCRIPTION OF THE DRAWINGS

FIG. 1 is a cross-sectional view illustrating feature part of a structure of a semiconductor device according to a first embodiment of the present invention.

FIGS. 2A through 2C are cross-sectional views of feature part illustrating respective steps for fabricating a semiconductor device according to the first embodiment of the present invention in the order of process sequence.

FIG. 3 is a cross-sectional view illustrating feature part of a structure of a semiconductor device according to a second embodiment of the present invention.

FIGS. 4A through 4C are cross-sectional views of feature part illustrating respective steps for fabricating a semiconductor device according to the second embodiment of the present invention in the order of process sequence.

FIG. 5 is a cross-sectional view illustrating a structure of a known NMIS transistor.

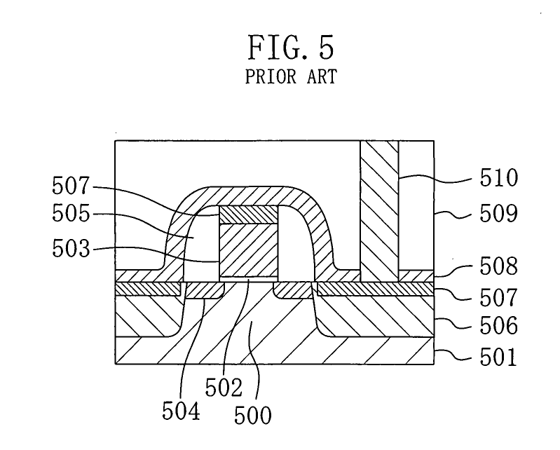

### DESCRIPTION OF THE PREFERRED EMBODIMENTS

(First Embodiment)

Hereafter, a structure of a semiconductor device according to a first embodiment of the present invention will be described with reference to the accompanying drawings.

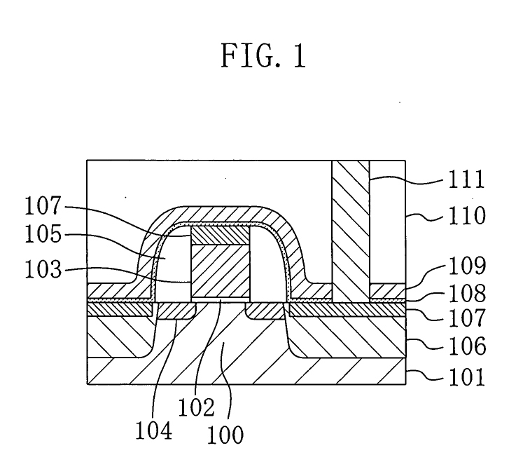

FIG. 1 is a cross-sectional view illustrating feature part of a structure of a semiconductor device according to the first embodiment of the present invention.

As shown in FIG. 1, in a semiconductor substrate 101 of, for example, silicon, an active region 100 is formed so as to be surrounded by isolation regions (not shown) and include a p-well (not shown) formed therein. On the active region 100, a gate electrode 103 is formed so as to have a thickness of about 110 nm with a gate insulating film 102 interposed therebetween. The gate insulating film 102 is formed of, for example, an SiON base film and has a thickness of about 2 nm. The gate electrode 103 includes, as an upper layer, a silicide region 107 of, for example, NiSi with a thickness of about 20 nm. A gate length of the gate electrode 103 is about 50 nm. In parts of the active region 100 located at both sides of the gate electrode 103, respectively, for example, an n-type impurity such as arsenic, phosphorus and the like is implanted thereto to form n-type source/drain regions (n-type extension regions or n-type LDD regions) 104 with a shallow junction depth.

Moreover, sidewalls 105 are formed on side surfaces of the silicide region 107, the gate electrode 103 and the gate insulating film 102 as well as on the active region 100. A width of bottom part of the sidewall 105 is about 50 nm. In parts of the active region 100 located at outer sides of the sidewalls 105, an n-type impurity such as arsenic, phosphorus and the like is implanted thereto to form n-type source/drain regions 106 each including, as an upper layer thereof, a silicide region 107 with a thickness of about 20 nm and having a greater junction depth than a depth of the source/drain regions 104.

Over the semiconductor substrate 101, an underlying insulating film 108 is formed using ALD (atomic layer deposition) so as to cover the silicide regions 107 on the gate electrode 103 and the source/drain regions 106 as well as the sidewall 105. In this case, the underlying insulating film 108 is made of a silicon nitride film formed using ALD at a deposition temperature of 400° C. so as to have at thickness of 3 nm. In the silicon nitride film, a composition ratio of nitride to silicon is preferably 1.2 or more. Furthermore, a thickness of the silicon nitride film may be 0.3 nm or more and 10 nm or less.

On the underlying insulating film 108, a contact liner film 109 for applying a tensile stress in the gate length direction in a channel region is formed using plasma CVD. In this case, when as the contact liner film 109, a silicon nitride film having a tensile stress of 1.4 GPa was deposited to a thickness of 25 nm using plasma CVD, a thickness of the silicon nitride film was equivalent to 25 nm even on the silicide region 107 as the upper layer of the n-type source/drain regions 106 and a doped region (non-silicide region which is not shown) in which the silicide region 107 does not exist. A thickness of the contact liner film 109 is preferably 15 nm or more and 50 nm or less and more preferably 20 nm or more and 30 nm or less.

On the contact liner film 109, an interlevel insulating film 110 is formed of a silicon oxide film represented by, for example, a TEOS film so as to have a flattened surface and a thickness of about 350 nm. In the interlevel insulating film 110, the contact liner film 109 and the underlying insulating film 108, a contact plug 111 is formed so as to pass though these films and have a lower end reaching the silicide region 107.

Next, a method for fabricating a semiconductor device according to the first embodiment of the present invention will be described with reference to the accompanying drawings.

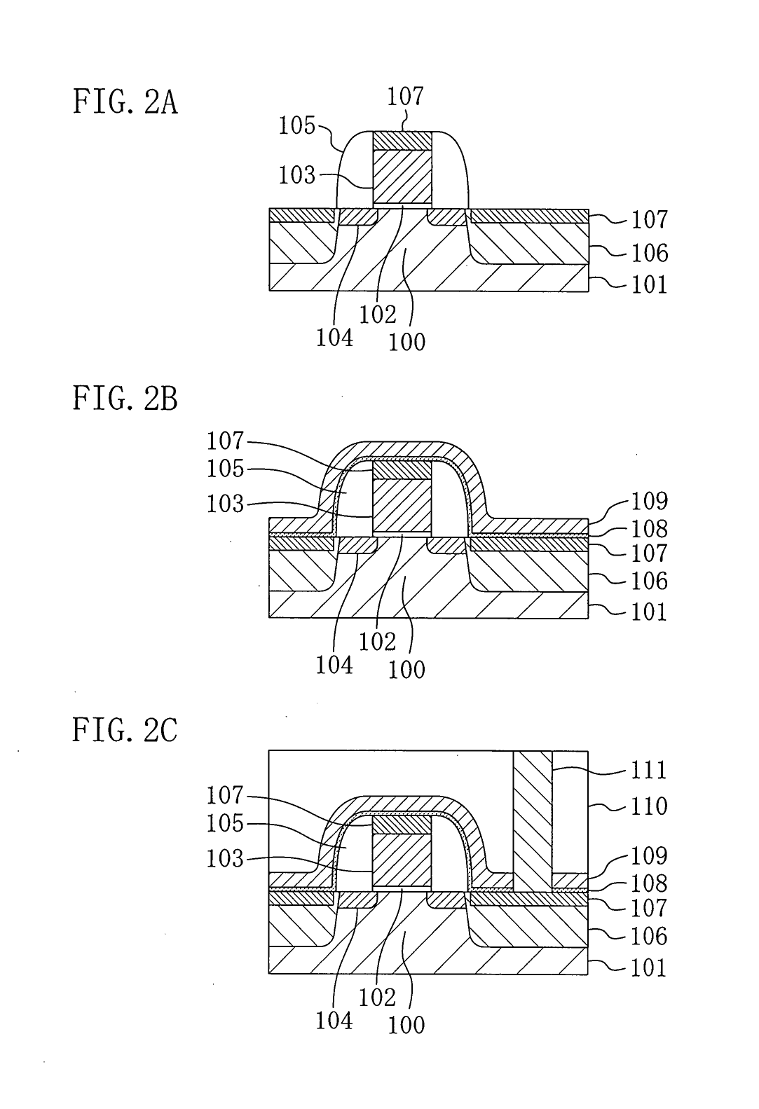

FIGS. 2A through. 2C are cross-sectional views of feature part illustrating respective steps for fabricating a semiconductor device according to the first embodiment of the present invention in the order of process sequence.

First, as shown in FIG. 2A, in part of a semiconductor substrate 101 of, for example, silicon surrounded by isolation regions (not shown) selectively formed, for example, using STI (shallow trench isolation) or the like, a p-well (not shown) is formed by ion implantation, thereby forming an active region 100. Subsequently, after forming a gate insulating film formation film of, for example, an SiON base film on the semiconductor substrate 101 so as to have a thickness of about 2 nm, a gate electrode film formation film is formed of, for example, polysilicon so as to have a thickness of about 120 nm. Then, using lithography and dry etching, a gate insulating film 102 and a gate electrode 103 are formed of the gate insulating film formation film and the gate electrode formation film, respectively. A gate length of the gate electrode 103 is about 50 nm.

Subsequently, using the gate electrode 103 as a mask, an n-type impurity such as arsenic, phosphorus and the like is ion implanted to the active region 100, for example, at an implantation energy of 3 keV and an implantation dose of 1×10¹⁴/cm², thereby forming n-type source/drain regions 104 each having a relatively shallow junction depth (i.e., a shallower junction depth than that of source/drain regions 106).

Then, an insulating film is formed of a silicon oxide film of, for example, SiO₂ over the semiconductor substrate 101 so as to have a thickness of about 50 nm and cover the gate electrode 103. Then, the insulating film is etched back to form sidewalls 105 on side surfaces of the gate insulating film 102 and the gate electrode 103.

Thereafter, using the gate electrode 103 and the sidewall 105 as a mask, an n-type impurity such as arsenic, phosphorus and the like is ion implanted to parts of the active region 100 located at outer sides of the sidewalls 105, for example, at an implantation energy of 10 keV and an implantation dose of 1×10¹⁵/cm², thereby forming n-type source/drain regions 106 each having a relatively great junction depth (i.e., a greater junction depth than that of the source/drain regions 104).

Subsequently, after depositing a metal film such as cobalt, nickel and the like over the semiconductor substrate 101 to a thickness of about 10 nm, heat treatment is performed to the semiconductor substrate 101 to bring silicon and metal of the metal film into reaction. Thus, silicide regions 107, for example, of NiSi is formed as an upper layer of each of the n-type source/drain regions 106 located at outer sides of the sidewalls 105 and a silicide region 107 is also formed as an upper layer of the gate electrode 103. In this case, upper part of the gate electrode 103 extending from an upper surface of the gate electrode 103 by about 10 nm is silicidized, so that a thickness of the gate electrode 103 after formation of the silicide region 107 is about 110 nm.

Next, as shown in FIG. 2B, using ALD, an underlying insulating film 108 is formed over the semiconductor substrate 101 at a deposition temperature of 400° C. or less so as to cover the silicide region 107 as the upper layer of each of the gate electrode 103 and the n-type source/drain regions 106 and the sidewall 105. In this case, the underlying insulating film 108 is made of a silicon nitride film formed using ALD at a deposition temperature of 400° C. so as to have a thickness of 3 nm. In the silicon nitrogen film, the ratio of nitrogen to silicon is preferably 1.2 or more. A thickness of the silicon nitride film may be 0.3 nm or more and 10 nm or less.

Subsequently, using plasma CVD, a contact liner film 109 is formed on the underlying insulating film 108 at a deposition temperature of 250° C. more and 450° C. or more. In this case, when as the contact liner film 109, a silicon nitride film having a tensile stress of 1.4 GPa was deposited to a thickness of 25 nm using plasma CVD, a thickness of the silicon nitride film was equivalent to 25 nrm even on the silicide region 107 as the upper layer of each of the n-type source/drain regions 106 and a doped region (non-silicide region which is not shown) in which the silicide region 107 does not exist. A thickness of the contact liner film 109 is preferably 15 nm or more and 50 nm or less and more preferably 20 nm or more and 30 nm or less.

Next, as shown in FIG. 2C, a silicon oxide film represented by a TEOS film is deposited over the contact liner film 109 to a thickness of about 500 nm and then a surface of the silicon oxide film is flattened using CMP, thereby forming an interlevel insulating film 110 having a thickness of about 350 nm. Subsequently, using lithography and dry etching, a contact hole is formed in the interlevel insulating film 110, the contact liner film 109 and the underlying insulating film 108 so that the contact hole passes through the films and through which part of the silicide region 107 as the upper layer of each of the deep n-type source/drain regions 106 is exposed, and then a conductive film such as tungsten is filled in the contact hole, thereby forming a contact plug 111 with a lower end reaching the silicide region 107.

As has been described, in accordance with the semiconductor device and the fabrication method of the first embodiment of the present invention, the underlying insulating film 108 formed of a silicon nitride film using ALD is provided as an underlying layer of the contact liner film 109 formed of a silicon nitride film, using plasma CVD, which is a stress insulating film for applying a tensile stress in the gate length direction. Thus, the dependence of the contact liner film 109 on an underlying layer is eliminated to suppress reduction in thickness of the contact liner film 109. Accordingly, the thickness of the contact liner film 109 can be increased to raise an ON current of a transistor. Specifically, if a silicon nitride film is deposited to a thickness of 25 nm using plasma CVD, a silicon nitride film is deposited only to a thickness of 20 nm on a slicide region in a doped region in the known example, but according to this embodiment, a silicon nitride film can be deposited to a thickness of 25 nm on a silicide region in each of the n-type source/drain regions 106. That is, according to this embodiment, 25% increase in thickness of the silicon nitride is achieved, compared to the known example. Accordingly, an ON current of a MIS transistor can be improved. Moreover, the contact liner film 109 has a uniform thickness of 25 nm on the silicide region 107 in each of the n-type source/drain regions 106 and in the doped region (non-silicide region which is not shown) in which the silicide region 107 does not exist and therefore etching conditions for the contact hole for forming the contact plug 111 can be simply set.

As a material for the underlying insulating film 108, in view of only eliminating the dependence of a contact liner film on an underlying layer, some other insulating film such as a silicon oxide film may be used. However, as in this embodiment, if the underlying insulating film 108 of a silicon nitride film is formed using ALD, the underlying insulating film 108 itself does not have the dependence on an underlying layer and the underlying insulating film 108 can be formed so as to have a uniform, thin film (e.g., 3 nm). Thus, the thickness of the contact liner film 109 can be increased and, furthermore, change of properties of the silicide region 107 can be prevented. Therefore, this embodiment is more preferable in terms of integration.

Also, in terms of integration, it is preferable to form the silicide region 107 and the underlying insulating film 108 of the same material. Moreover, it is more preferable to form each of the silicide region 107 and the underlying insulating film 108 of a silicon nitride film, as has been described.

In this embodiment, the case where the silicon nitride film formed using ALD has a thickness of 3 nm, the deposition temperature is 400° C. and the silicon nitride film formed using plasma CVD has a thickness of 25 nm and a tensile stress of 1.4 GPa has been described. However, those conditions are not limited to the above-described values.

In this embodiment, the semiconductor device including an NMIS transistor and the method for fabricating the semiconductor device have been described. However, even when the semiconductor device includes a PMIS transistor, the same effects as those described above can be achieved in the PMIS transistor by forming, on the underlying insulating film 108, the contact liner film 109 of a silicon nitride film or the like which is a stress insulating film for applying a compressive stress in the gate length direction in a channel region.

Moreover, in this embodiment, the sidewalls 105 may be formed on an inner surface of an insulating film formed on side surfaces of the silicide region 107, the gate electrode 103 and the gate insulating film 102 as well as on the active region 100 so as to have an L-shape cross section. Furthermore, an insulating film having an I-shape cross-section may be provided so as to be interposed between an insulating film with an L-shape cross-section and each of side surfaces of the silicide region 107, the gate electrode 103 and the gate insulating film 102.

(Second Embodiment)

Hereafter, a structure of a semiconductor device according to a second embodiment of the present invention will be described with reference to the accompanying drawings.

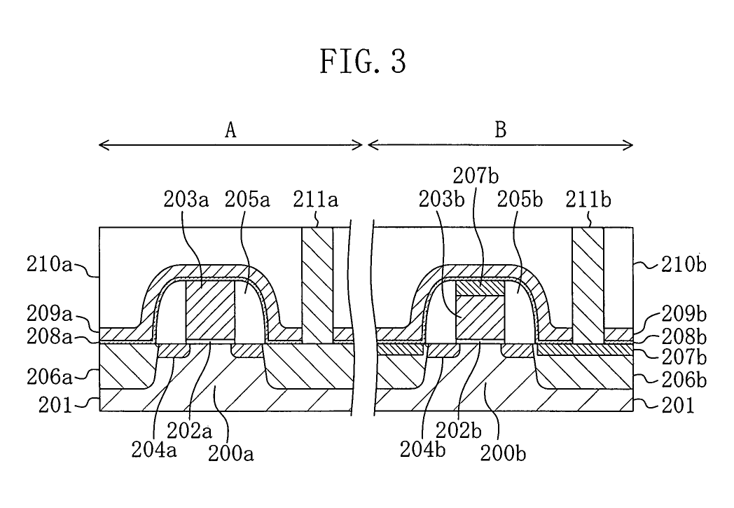

FIG. 3 is a cross-sectional view illustrating feature part of a structure of a semiconductor device according to the second embodiment of the present invention.

In a region A of FIG. 3 in which an NMIS transistor is formed, an active region 200a is formed in a semiconductor substrate 201 of, for example, silicon so as to be surrounded by isolation regions and include a p-well (not shown) formed therein. On the active region 200a, a gate electrode 203a is formed so as to have a thickness of about 120 nm with a gate insulating film 202a of, for example, an SiON base film with a thickness of about 2 nm interposed therebetween. A gate length of the gate electrode 203a is about 50 nm.

In parts of the active region 200a located at both sides of the gate electrode 203a, respectively, an n-type impurity such as arsenic, phosphorus and the like is implanted thereto to form n-type source/drain regions (n-type extension regions or n-type LDD regions) 204a with a relatively shallow junction depth. Moreover, sidewalls 205a are formed on side surfaces of the gate electrode 203a and the gate insulating film 202a as well as on the active region 200a. A width of bottom part of each of the sidewalls 205a is about 50 nm. In parts of the active region 200a located at outer sides of the sidewalls 205a, an n-type impurity such as arsenic, phosphorus and the like is implanted thereto to form n-type source/drain regions 206a with a relatively great junction depth (i.e., a greater junction depth than a depth of the source/drain regions 204a).

Over the semiconductor substrate 201, an underlying insulating film 208a is formed using ALD so as to cover the gate electrode 203a and the sidewalls 205a.

On the underlying insulating film 208a, a contact liner film 209a for applying a

tensile stress in the gate length direction in a channel region is formed using plasma CVD.

On the contact liner film 209a, an interlevel insulating film 210a is formed of a silicon oxide film represented by, for example, a TEOS film so as to have a flattened surface and a thickness of about 350 nm. In the interlevel insulating film 210a, the contact liner film 209a and the underlying insulating film 208a, a contact plug 211a is formed so as to pass though the films and have a lower end reaching part of the n-type source/drain regions 206a.

On the other hand, in a region B of FIG. 3 in which an NMIS transistor is formed, an active region 200b is formed in a semiconductor substrate 201 so as to be surrounded by isolation regions and include a p-well (not shown) formed therein. On the active region 200b, a gate electrode 203b is formed so as to have a thickness of about 110 nm and include, as an upper layer, a silicide region 207b of, for example, NiSi with a thickness of about 20 nm with a gate insulating film 202b of, for example, an SiON base film with a thickness of about 2 nm interposed therebetween. In parts of the active region 200b located at both sides of the gate electrode 203b, respectively, an n-type impurity such as As, P and the like is implanted thereto to form n-type source/drain regions (n-type extension regions or n-type LDD regions) 204b with a relatively shallow junction depth (i.e., a shallower depth than a depth of source/drain regions 206b). Moreover, sidewalls 205b are formed on side surfaces of the silicide region 207b, the gate electrode 203b and the gate insulating film 202b as well as on the active region 200b. A width of bottom part of each of the sidewalls 205b is about 50 nm. In parts of the active region 200b located at outer sides of the sidewalls 205b, an n-type impurity is implanted thereto to form n-type source/drain regions 206b with a relatively great junction depth (i.e., a greater junction depth than a depth of the source/drain regions 204b) each including, as an upper layer, a silicide region 207b with a thickness of about 20 nm.

Over the semiconductor substrate 201, an underlying insulating film 208b is formed using ALD so as to be continuous in a unified manner and cover the gate electrode 203b and the sidewalls 205b. In this case, the underlying insulating film 208a and the underlying insulating film 208b are made of a silicon nitride film formed using ALD at a deposition temperature of 400° C. so as to have at thickness of 3 nm. In the silicon nitride film, a composition ratio of nitride to silicon is preferably 1.2 or more. Furthermore, a thickness of the silicon nitride film may be 0.3 nm or more and 10 nm or less.

On the underlying insulating film 208b, a contact liner film 209b for applying a tensile stress in the gate length direction in a channel region is formed using plasma CVD so as to be continuous in a unified manner. In this case, when as the contact liner film 209a and the contact liner film 209b, a silicon nitride film having a tensile stress of 1.4 GPa was deposited to a thickness of 25 nm using plasma CVD, the thickness of the silicon nitride film was equivalent to 25 nm on both of the silicide region 207b as the upper layer of each of the n-type source/drain regions 206b, and the source/drain regions 206a (non-silicide region) in which a silicide region does not exist. The thickness of the contact liner film 209a and the contact liner film 209b is preferably 15 nm or more and 50 nm or less and more preferably 20 nm or more and 30 nm or less.

On the contact liner film 209b, an interlevel insulating film 210b is formed of a silicon oxide film represented by, for example, a TEOS (tetraethylothosilicate) film so as to have a flattened surface and a thickness of about 350 nm. In the interlevel insulating film 210b, the contact liner film 209b and the underlying insulating film 208b, a contact plug 211b, is formed so as to pass though the films and have a lower end reaching the silicide region 207b.

Hereafter, a method for fabricating a semiconductor device according to the second embodiment of the present invention will be described with reference to the accompanying drawings.

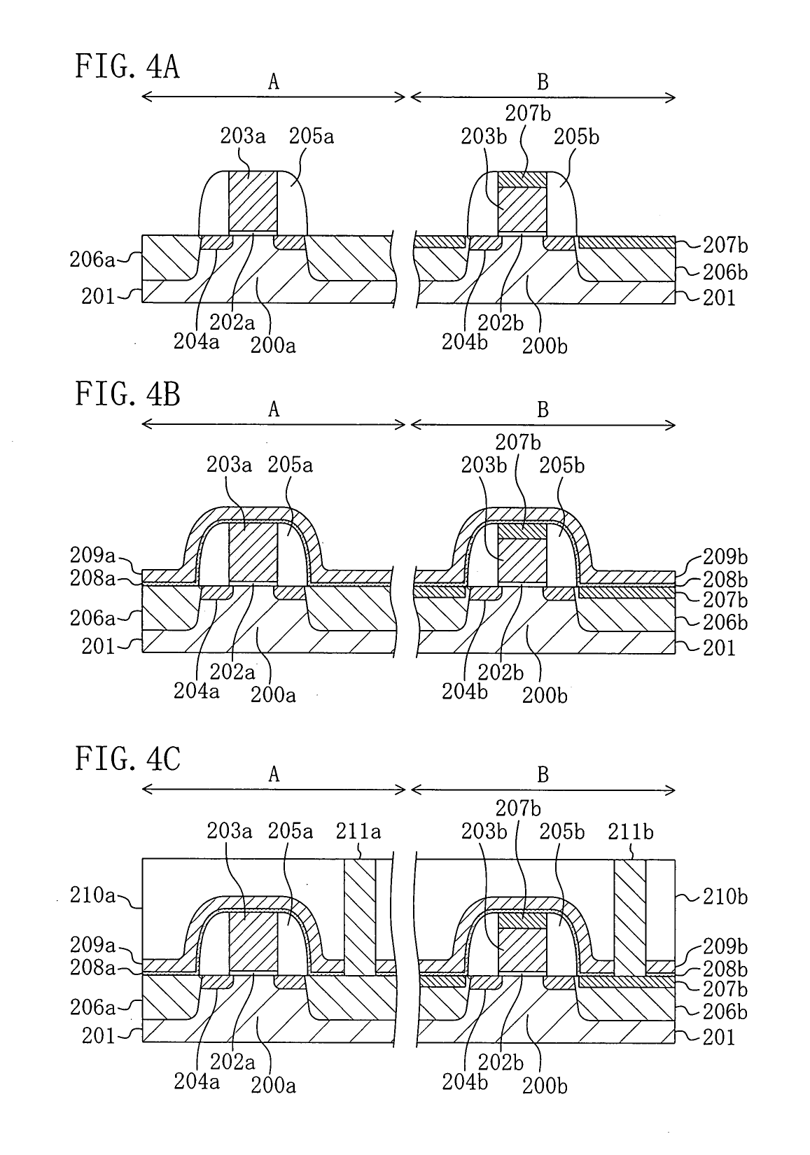

FIGS. 4A through 4C are cross-sectional views of feature part illustrating respective steps for fabricating a semiconductor device according to the second embodiment of the present invention in the order of process sequence.

First, as shown in FIG. 4A, in part of a semiconductor substrate 201 surrounded by isolation regions (not shown), using a predetermined mask, a p-well (not shown) is selectively formed by ion implantation of a p-type impurity, thereby forming an active region 200a in a region A. In the same manner, using a predetermined mask, a p-well (not shown) is selectively formed by ion implantation of a p-type impurity, thereby forming an active region 200b in a region B. Subsequently, on the active region 200a, a gate insulating film 202a is formed of, for example, an SiON base film so as to have a thickness of about 2 nm and then a gate electrode 203a is formed of, for example, polysilicon so as to have a thickness of about 120 nm. Also, on the active region 200b, a gate insulating film 202b is formed of, for example, an SiON base film so as to have a thickness of about 2 nm and a gate electrode 203b is formed of, for example, polysilicon so as to have a thickness of about 120 nm.

Subsequently, using the gate electrode 203a as a mask, in parts of the active region 200a located at both sides of the gate electrode 203a, respectively, an n-type impurity is implanted thereto to form n-type source/drain regions 204a with a shallow junction depth. Also, using the gate electrode 203b as a mask, in parts of the active region 200b located at both sides of the gate electrode 203b, respectively, an n-type impurity is implanted thereto to form n-type source/drain regions 204b with a shallow junction depth.

Then, sidewalls 205a are formed on side surfaces of the active region 200a as well as the gate insulating film 202a and the gate electrode 203a. A width of bottom part of each of the sidewalls 205a is about 50 nm. Also, sidewalls 205b are formed on side surfaces of the active region 200b as well as the gate insulating film 202b and the gate electrode 203b. A width of bottom part of each of the sidewalls 205b is about 50 nm.

Thereafter, using the gate electrode 203a and the sidewalls 205a as a mask, in parts of the active region 200a located at outer sides of the sidewalls 205a, an n-type impurity is implanted thereto to form n-type source/drain regions 206a with a great junction depth. Also, using the gate electrode 203b and the sidewalls 205b as a mask, in parts of the active region 200b located at outer sides of the sidewalls 205b, an n-type impurity is implanted thereto to form n-type source/drain regions 206b, with a great junction depth.

Subsequently, after depositing a metal film such as cobalt, nickel and the like over the region B, heat treatment is performed to the region B, thereby forming a silicide region 207b with a thickness of about 20 nm as an upper layer of each of the source/drain regions 206b, located at the outer sides of the sidewalls 205b and the gate electrode 203b. In this case, the silicide region 207b is selectively formed so that a silicide region is not formed as an upper layer of each of the n-type source/drain regions 206a located at the outer sides of the sidewalls 205a and the gate electrode 203a. For example, by performing heat treatment after removal of a metal film formed in the region A or forming a silicidization stopper film made of a silicon oxide film on the region A before forming a metal film, the silicide region 207b is formed only in the region B.

Next, as shown in FIG. 4B, over the semiconductor substrate 201, using ALD, a silicon nitride film is formed so as to cover the gate electrode 203a, the sidewall 205a, the gate electrode 203b and the sidewall 205b, thereby forming an underlying insulating film 208a in the region A and an underlying insulating film 208b in the region B. In this case, each of the underlying insulating film 208a and the underlying insulating film 208b is made of a silicon nitride film formed by ALD at a deposition temperature of 400° C. so as to have a thickness of 3 nm. In the silicon nitrogen film, the ratio of nitrogen to silicon is preferably 1.2 or more. A thickness of the silicon nitride film is 0.3 nm or more and 10 nm or less.

Subsequently, on the underlying insulating films 208a and 208b, a silicon nitride film for applying a tensile stress in the gate length direction in a channel region is formed using plasma CVD. Thus, a contract liner film 209a and a contact liner film 209b are formed in the region A and the region B, respectively. In this case, when as the contact liner films 209a and 209b, a silicon nitride film having a tensile stress of 1.4 GPa was deposited to a thickness of 25 nm using plasma CVD, the thickness of the silicon nitride film was equivalent to 25 nm even on the silicide region 207b as the upper layer of each of the n-type source/drain regions 206b, and the n-type source/drain regions 206a (non-silicide regions) in which the silicide region does not exist. The thickness of the contact liner films 209a and 209b is preferably 15 nm or more and 50 nm or less and more preferably 20 nm or more and 30 nm or less. Note that the silicon nitride film having a tensile stress is formed in the same manner as in the first embodiment.

Next, as shown in FIG. 4C, after depositing a silicon oxide film represented by a TEOS film over the contact liner films 209a and 209b to a thickness of about 500 nm, a surface of the silicon oxide film is flattened using CMP, thereby forming an interlevel insulating film with a thickness of about 350 nm. Thus, an interlevel insulating film 210a and an interlevel insulating film 210b are formed in the region A and the region B, respectively. Subsequently, using lithography and dry etching, a contact hole is formed in the interlevel insulating film 210a, the contact liner film 209a and the underlying insulating film 208a so that the contact hole passes through the films and through which part of the n-type source/drain regions 206a is exposed, and then a conductive film such as tungsten is filled in the contact hole, thereby forming a contact plug 211a with a lower end reaching part of the n-type source/drain regions 206a. In the same manner, a contact hole is formed in the interlevel insulating film 210b, the contact liner film 209b and the underlying insulating film 208b so that the contact hole passes through the films and through which part of the silicide region 207b as an upper layer of each of the n-type source/drain regions 206b, is exposed, and then a conductive film such as tungsten is filled in the contact hole, thereby forming a contact plug 211b, with a lower end reaching the silicide region 207b as an upper layer of the n-type source/drain regions 206b.

As has been described, in accordance with the semiconductor device and the fabrication method of the second embodiment of the present invention, a structure including the contact liner films 209a and 209b formed using plasma CVD on the underlying insulating films 208a and 208b formed using ALD is used for a semiconductor device in which an NMIS transistor in the region A which does not include a silicide region and an NMIS transistor in the region B which includes the silicide region 207 are provided on the same wafer. Thus, the dependence of the contact liner films 209a and 209b on underlying layers can be eliminated and a uniform thickness of 25 nm can be achieved for the contact liner films 209a and 209b even in the non-silicide region in which the silicide region 207b does not exist.

Regarding this point, according to the experiments conducted by the present inventor, in the known semiconductor device in which an NMIS transistor which does not include a silicide region and an NMIS transistor including a silicide region are provided on the same wafer and an underlying insulating film according to the present invention is not provided under a contact liner film, the following result was obtained. When a silicon nitride film was deposited as a contact liner film to a thickness of 25 nm, a thickness of part of the silicon nitride film located in a non-silicide region in which a silicide region is not formed was 25 nm but a thickness of part of the silicon nitride film located on a silicide region was only 20 nm. As this result shows, in the known semiconductor device, the thickness of the contact liner film varies on the wafer surface, specifically, on a doped region, and thus modification of contact etching conditions is difficult. Specifically, etching conditions are set in accordance with a thickness of a thick contact liner film formed in a transistor side in which a silicide region is not formed, contact etching is excessively performed to a thin contact liner film formed in a transistor side in which a silicide layer is formed, thus resulting in increase in junction leakage current. On the other hand, if etching conditions are set in accordance with the thin contact liner film, the thick contact liner film is under-etched, thus resulting in contact open defects and then reduction in yield.

In contrast, according to this embodiment, the contact liner films 209a and 209b with a uniform thickness can be obtained, so that etching conditions for contact holes for forming the resistors 211a and 211b, can be simply set and the above-described known problems can be avoided. Moreover, the thickness of the contact liner film 209b on the silicide region 207b is 25 nm and, as in the first embodiment, 25% increase in thickness of a contact liner film can be achieved, compared to a contact liner film having a thickness of 20 nm on a silicide region in the known semiconductor device. Accordingly, an ON current of a MIS transistor can be improved.

Moreover, for the same reason described in the first embodiment, in view of only eliminating the dependence of the contact liner films 209a and 209b on underlying layers, some other insulating film such as a silicon oxide film may be used as a material of the underlying insulating films 208a and 208b. However, in consideration of integration, the underlying insulating films 208a and 208b are preferably formed of a silicon nitride film. Also, as in the first embodiment, the underlying insulating films 208a and 208b and the contact liner films 209a and 209b are preferably formed of the same material.

In this embodiment, the case where the silicon nitride film formed using ALD has a thickness of 3 nm, the deposition temperature is 400° C. and the silicon nitride film formed using plasma CVD has a thickness of 25 nm and a tensile stress of 1.4 GPa has been described. However, those conditions are not limited to the above-described values.

Also, in this embodiment, the semiconductor device including two NMIS transistors and the method for fabricating the semiconductor device have been described. However, even if a semiconductor device includes two PMIS transistors or a combination of a single NMIS transistor and a single PMIS transistor, the same effects as the above-described effects can be achieved by forming, on the underlying insulating films 208a and 208b formed using ALD, the contact liner films 209a and 209b of a silicon nitride film which is a stress insulating film for applying a compressive stress in the gate length direction in a channel region.

In this embodiment, in the same manner as in the first embodiment, each of the sidewalls 205a and 205b may be formed on an inner surface of an insulating film having an L-shape cross section. Moreover, an insulating film having an I-shape cross-section may be further provided.

As has been described, the present invention is useful for a semiconductor device including a contact liner film formed using plasma CVD and a method for fabricating the semiconductor device.

What is claimed is:

1. A semiconductor device comprising a first MIS transistor formed on a first active region in a semiconductor substrate,
wherein the first MIS transistor comprises:
a first gate insulating film formed on the first active region;
a first gate electrode formed on the first gate insulating film;
first sidewall insulating films formed on side surfaces of the first gate electrode;
first source/drain regions formed at outer sides of the first sidewall insulating film in the first active region;
a silicide region formed as an upper layer of each of the first source/drain regions;
a first underlying insulating film formed over the first active region using ALD so as to cover the first gate electrode, the first insulating films and the silicide region; and
a first contact liner film formed on the first underlying insulating film using plasma CVD and made of a stress insulating film for applying a tensile or compressive stress in a gate length direction in a channel region.

2. The semiconductor device of claim 1, wherein the first underlying insulating film is made of silicon nitride film, and
the first contact liner film is made of a silicon nitride film.

3. The semiconductor device of claim 2, wherein in the silicon nitride film constituting the first underlying insulating film, a composition ratio of nitrogen to silicon is 1.2 or more.

4. The semiconductor device of claim 2, wherein the silicon nitride film constituting the first underlying insulating film has a thickness of 0.3 nm or more and 10 nm or less.

5. The semiconductor device of claim 2, wherein the silicon nitride film constituting the first contact liner film has a thickness of 15 nm or more and 50 nm or less.

6. The semiconductor device of claim 1, wherein the first MIS transistor is an N-type MIS transistor, and
the first contact liner film is made of a stress insulating film for applying a tensile stress in the gate length direction in the channel region.

7. The semiconductor device of claim 1, wherein the first MIS transistor is a P-type MIS transistor, and
the first contact liner film is made of a stress insulating film for applying a compressive stress in the gate length direction in the channel region.

8. The semiconductor device of claim 1, further comprising a second MIS transistor formed in a second active region which is different from the first active region in the semiconductor substrate,
wherein the second MIS transistor includes:
a second gate insulating film formed on the second active region;
a second gate electrode formed on the second gate insulating film;
second sidewall insulating films formed on side surfaces of the second gate electrode;
second source/drain regions formed at outer sides of the second sidewall insulating films in the second active region;
a second underlying insulating film formed over the second active region using ALD so as to cover the second gate electrode and the second insulating films; and
a second contact liner film formed on the second underlying insulating film using plasma CVD and made of a stress insulating film for applying a tensile or compressive stress in the gate length direction in the channel region, and
a thickness of the first contact liner on the silicide region in the first active region is equal to a thickness of the second contact liner film in the second active region.

9. The semiconductor device of claim 8, further comprising:
an interlevel insulating film formed over the first contact liner film and the second contact liner film;
a first contact plug formed so as to pass through the interlevel insulating film and the first contact liner film and reach the silicide region; and
a second contact plug formed so as to pass through the interlevel insulating film and the second contact liner film and reach part of the second source/drain regions.

10. A method for fabricating a semiconductor device, the method comprising the steps of:
a) forming a first gate insulating film over a first active region in a semiconductor substrate;
b) forming a first gate electrode on the first gate insulating film;
c) forming first sidewall films on side surfaces of the first gate electrode;
d) forming first source/drain regions at outer sides of the first sidewall films in the first active region;
e) forming a silicide region as an upper layer of each of the first source/drain regions;
f) forming a first underlying insulating film over the first active region using ALD so as to cover the first gate electrode, the first insulating films and the silicide region; and
g) forming a first contact liner film on the first underlying insulating film using plasma CVD and made of a stress insulating film for applying a tensile or compressive stress in a gate length direction in a channel region.

11. The method of claim 10, wherein the step f) includes a step of forming the first underlying insulating film of a silicon nitride film; and
the step g) includes a step of forming the first contact liner film of a silicon nitride film.

12. The method of claim 10, wherein
the step a) includes a step of forming a second gate insulating film on the second active region which is different from the first active region,.
the step b) includes a step of forming a second gate electrode on the second gate insulating film,
the step c) includes a step of forming second sidewall insulating films on side surfaces of the second gate electrode,
the step d) includes a step of forming second source/drain regions at outer sides of the second sidewall insulating films in the second active region,
in the step e), the silicide region is formed so as not to be located in upper layers of the second source/drain regions,
the step f) includes a step of forming a second underlying insulating film on the second active region using ALD so as to cover the second gate electrode and the second sidewall insulating films, and
the step g) includes a step of forming a second contact liner film on the second underlying insulating film using plasma CVD and made of a stress insulating film for applying a tensile or compressive stress in the gate length direction in the channel region.

13. The method of claim 12, further comprising after the step g):
the step h) of forming an interlevel insulating film on the first contact liner film and the second contact liner film; and
the step i) of forming a first contact plug and a second contact plug so that the first contact plug passes through the interlevel insulating film and the first contact liner film and reaches part of the silicide region and the second contact plug passes through the interlevel insulating film and the second contact liner film and reaches part of the second source/drain regions.
